(19) United States
(12) Patent Application Publication
(10) Pub. No.: US 2025/0293045 A1
(43) Pub. Date: Sep. 18, 2025

(54) METHOD FOR FABRICATING SEMICONDUCTOR DEVICE

(71) Applicant: Samsung Electronics Co., Ltd., Suwon-si (KR)

(72) Inventors: Jong Ho PARK, Suwon-si (KR); Sang Moon YUN, Cheonan-si (KR); Ryang Jo YOON, Cheonan-si (KR); Hyun Ju LEE, Suwon-si (KR); Jae Mok JUNG, Suwon-si (KR); Tae Oh HA, Suwon-si (KR); Ju Suk KANG, Suwon-si (KR); Jin Gyeong KIM, Cheonan-si (KR); Ji Won PARK, Cheonan-si (KR); Hye Ran CHOI, Cheonan-si (KR); Chi Sung IHN, Cheonan-si (KR)

(73) Assignees: Samsung Electronics Co., Ltd., Suwon-si (KR); Samyoung Pure Chemicals Co., Ltd., Cheonan-si (KR)

(21) Appl. No.: 18/893,089

(22) Filed: Sep. 23, 2024

(30) Foreign Application Priority Data
Mar. 12, 2024 (KR) 10-2024-0034372

(51) Int. Cl. H01L 21/3213; H01L 21/3205; H01L 21/768

(52) U.S. Cl. CPC H01L 21/32134; H01L 21/32051; H01L 21/32139; H01L 21/76834

(57) ABSTRACT

A method for fabricating a semiconductor device is provided. The method includes forming a first metal material layer on an upper surface of a substrate, the first metal material layer including titanium (Ti), forming a photoresist pattern in which a trench is formed on an upper surface of the first metal material layer, forming a first metal layer including gold (Au) in the trench, removing the photoresist pattern, and etching a portion of the first metal material layer using an etching composition such that a remaining portion of the first metal material layer under the first metal layer after etching becomes a second metal layer. The etching composition includes water, an oxidizer, a first chelating agent including a hydroxy phosphonic acid compound, a second chelating agent including a polyamine compound, and an alkali.

### CROSS-REFERENCE TO RELATED APPLICATION

This application claims priority from Korean Patent Application No. 10-2024-0034372 filed on Mar. 12, 2024 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a method for fabricating a semiconductor device. Specifically, the present disclosure relates to a method for fabricating a semiconductor device including selectively etching titanium (Ti) using an etching composition.

### Description of Related Art

Recently, with rapid spread of information media, a function of a semiconductor device is developing rapidly. Recently, high integration of the semiconductor device is required for a low cost and a high quality to secure competitiveness. For the high integration, a semiconductor package includes a stack of a plurality of semiconductor chips, wherein semiconductor chips may be electrically connected to each other using a redistribution layer.

A metal wiring included in the redistribution layer may be formed by stacking a plurality of metal layers. For example, the plurality of metal layers included in the metal wiring may include a metal layer including titanium (Ti) and a metal layer including gold (Au). In a process of fabricating the metal wiring, an etching composition may be used to selectively etch titanium (Ti). In this case, an oxidizer included in the etching composition may react with gold (Au) to produce oxygen (O₂). The oxygen (O₂) causes problems in which other metals included in the metal wiring are oxidized or the metal layer including titanium (Ti) is excessively etched. For this reason, research on the etching composition to solve the above problem is in progress.

### SUMMARY

A purpose of the present disclosure is to provide a method for fabricating a semiconductor device in which in a structure in which a metal layer including titanium (Ti), a metal layer including copper (Cu), and a metal layer including gold (Au) are stacked, the metal layer including titanium (Ti) may be selectively etched using an etching composition including a hydroxy phosphonic acid compound, and a polyamine compound, thereby preventing the metal layer including copper (Cu) from being discolored, and reducing an etching amount of the metal layer including titanium (Ti), such that stability of the metal layer including titanium (Ti) may be improved.

According to some embodiments of the present disclosure, there is provided a method for fabricating a semiconductor device, including forming a first metal material layer on an upper surface of a substrate, the first metal material layer including titanium (Ti), forming a photoresist pattern in which a trench is formed on an upper surface of the first metal material layer, forming a first metal layer including gold (Au) in the trench, removing the photoresist pattern, and etching a portion of the first metal material layer using an etching composition, such that a remaining portion of the first metal material layer under the first metal layer after etching becomes a second metal layer. The etching composition includes water, an oxidizer, a first chelating agent including a hydroxy phosphonic acid compound, a second chelating agent including a polyamine compound, and an alkali.

According to some embodiments of the present disclosure, there is provided a method for fabricating a semiconductor device, including forming a via in a substrate, at least a portion of the via protruding in a vertical direction from an upper surface of the substrate, forming a passivation layer on the upper surface of the substrate, the passivation layer surrounding a portion of a sidewall of the via, forming a first metal material layer on an upper surface of the passivation layer and an upper surface of the via, the first metal material layer including titanium (Ti), forming a first metal layer on an upper surface of the first metal material layer, the first metal layer including gold (Au), and etching a portion of a sidewall of the first metal material layer using an etching composition, such that a remaining portion of the first metal material layer under the first metal layer after etching becomes a second metal layer. A width in a horizontal direction of the second metal layer is smaller than a width in the horizontal direction of the first metal layer. Each of both opposing sidewalls in the horizontal direction of the second metal layer is recessed than each of both opposing sidewalls in the horizontal direction of the first metal layer. The etching composition includes an oxidizer including hydrogen peroxide (H₂O₂), a first chelating agent including a hydroxy phosphonic acid compound, a second chelating agent including a polyamine compound, and an alkali.

According to some embodiments of the present disclosure, there is provided a method for fabricating a semiconductor device, including forming a via in a substrate, at least a portion of the via protruding in a vertical direction from an upper surface of the substrate, forming a passivation layer on the upper surface of the substrate, the passivation layer surrounding a portion of a sidewall of the via, forming a first metal material layer on an upper surface of the passivation layer and an upper surface of the via, the first metal material layer including titanium (Ti), forming a second metal material layer being in contact with an upper surface of the first metal material layer, the second metal material layer including a metal different from a metal of the first metal material layer, forming a photoresist pattern in which a trench is formed on the upper surface of the first metal material layer, forming a third metal layer in the trench, the third metal layer including a metal different from each of the metal of the first metal material layer and the metal of the second metal material layer, forming a first metal layer being in contact with an upper surface of the third metal layer in the trench, the first metal layer including gold (Au), removing the photoresist pattern, and etching each of a portion of the first metal material layer and a portion of the second metal material layer using an etching composition, such that a remaining portion of the second metal material layer under the third metal layer after etching becomes a fourth metal layer and a remaining portion of the first metal material layer under the fourth metal layer after etching becomes a second metal layer. A width in a horizontal direction of the fourth metal layer is smaller than a width in the horizontal direction of the first metal layer. A width in the horizontal direction of the second metal layer is smaller than the width in the horizontal direction of the fourth metal layer. Each of both opposing sidewalls in the horizontal direction of the fourth metal layer is recessed than each of both opposing sidewalls in the horizontal direction of the first metal layer. Each of both opposing sidewalls in the horizontal direction of the second metal layer is recessed than each of both opposing sidewalls in the horizontal direction of the fourth metal layer. The etching composition includes an oxidizer including hydrogen peroxide (H₂O₂), a first chelating agent including a hydroxy phosphonic acid compound, a second chelating agent including a polyamine compound, and an alkali.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means illustrated in the claims and combinations thereof.

### BRIEF DESCRIPTION OF DRAWINGS

The above and other aspects and features of the present disclosure will become more apparent by describing in detail embodiments thereof with reference to the attached drawings, in which:

FIG. 1 is a diagram for illustrating a semiconductor device fabricated by a method for fabricating a semiconductor device according to some embodiments of the present disclosure;

FIGS. 2 to 8 are diagrams of intermediate structures corresponding to intermediate steps of a method for fabricating a semiconductor device according to some embodiments of the present disclosure;

FIG. 9 is a diagram for illustrating a semiconductor device fabricated by a method for fabricating a semiconductor device according to further some embodiments of the present disclosure;

FIGS. 10 to 13 are diagrams of intermediate structures corresponding to intermediate steps of a method for fabricating a semiconductor device according to further some embodiments of the present disclosure;

FIG. 14 is a diagram for illustrating a semiconductor device fabricated by a method for fabricating a semiconductor device according to still further some embodiments of the present disclosure; and

FIGS. 15 to 18 are diagrams of intermediate structures corresponding to intermediate steps of a method for fabricating a semiconductor device according to still further some embodiments of the present disclosure.

### DETAILED DESCRIPTIONS

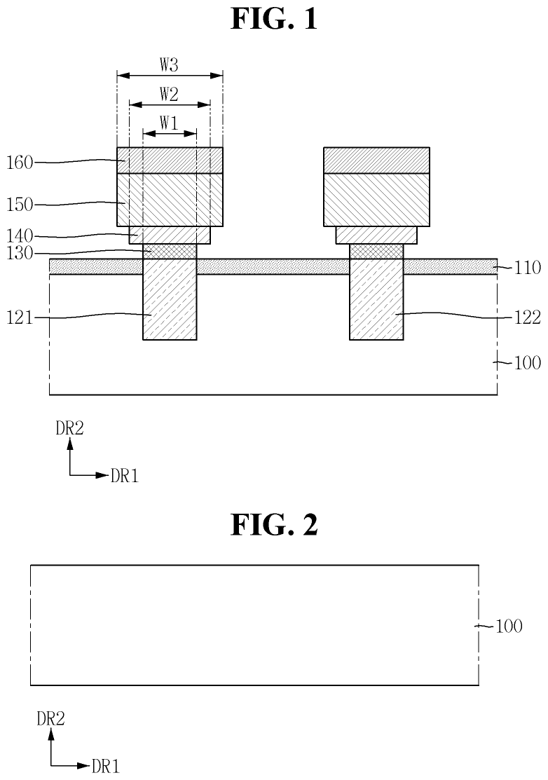

Hereinafter, with reference to FIG. 1, a semiconductor device fabricated by a method for fabricating a semiconductor device according to some embodiments of the present disclosure is described.

FIG. 1 is a diagram for illustrating a semiconductor device fabricated by a method for fabricating a semiconductor device according to some embodiments of the present disclosure.

Referring to FIG. 1, the semiconductor device fabricated by a method for fabricating a semiconductor device according to some embodiments of the present disclosure includes a substrate 100, a passivation layer 110, a first via 121, a second via 122, a first metal layer 160, a second metal layer 130, a third metal layer 150, and a fourth metal layer 140.

For example, the substrate 100 may be a substrate in a form of each of semiconductor chips into which a wafer is divided. In some alternative embodiments, the substrate 100 may be a substrate in a form of a wafer. When the substrate 100 is the substrate in a form of each of semiconductor chips into which a wafer is divided, the substrate 100 may be, for example, a memory semiconductor chip or a logic semiconductor chip.

When the substrate 100 is a logic semiconductor chip, the chip may be designed in various ways in consideration of an operation to be performed by the chip. When the substrate 100 is a memory semiconductor chip, the memory semiconductor chip may be, for example, a non-volatile memory chip.

Specifically, the memory semiconductor chip may be a flash memory chip. More specifically, the memory semiconductor chip may be either a NAND flash memory chip or a NOR flash memory semiconductor chip. However, the present disclosure is not limited thereto. In some alternative embodiments, the memory semiconductor chip may include one of dynamic random-access memory (DRAM), phase-change random-access memory (PRAM), magneto-resistive random-access memory (MRAM), and resistive random-access memory (RRAM).

Hereinafter, a horizontal direction DR1 may be defined as a direction parallel to an upper surface of the substrate 100. A vertical direction DR2 may be defined as a direction perpendicular to the horizontal direction DR1. That is, the vertical direction DR2 may be defined as a direction perpendicular to the upper surface of the substrate 100.

The first via 121 may be disposed in the substrate 100. For example, at least a portion of the first via 121 may protrude from the upper surface of the substrate 100 in the vertical direction DR2. That is, a vertical level of the upper surface of the first via 121 may be higher than that of the upper surface of the substrate 100. The second via 122 may be disposed in the substrate 100. The second via 122 may be spaced from the first via 121 in the horizontal direction DR1. For example, at least a portion of the second via 122 may protrude from the upper surface of the substrate 100 in the vertical direction DR2. That is, a vertical level of the upper surface of the second via 122 may be higher than that of the upper surface of the substrate 100. For example, the upper surface of the second via 122 may be coplanar with the upper surface of the first via 121. Each of the first via 121 and the second via 122 may include a conductive material.

The passivation layer 110 may be disposed on the upper surface of the substrate 100. The passivation layer 110 may be in contact with the upper surface of the substrate 100. For example, the passivation layer 110 may surrounds each of a sidewall of a portion of the first via 121 and a sidewall of a portion of the second via 122 that protrude in the vertical direction DR2 from the upper surface of the substrate 100. For example, the passivation layer 110 may contact each of the sidewall of the first via 121 and the sidewall of the second via 122. For example, an upper surface of the passivation layer 110 may be coplanar with each of the upper surface of the first via 121 and the upper surface of the second via 122. However, the present disclosure is not limited thereto. The passivation layer 110 may include an insulating material. For example, the passivation layer 110 may include a nitride film or an oxide film.

The second metal layer 130 may be disposed on each of the upper surface of the first via 121 and the upper surface of the second via 122. For example, a portion of the second metal layer 130 disposed on the upper surface of the second via 122 may be spaced apart from a portion of the second metal layer 130 disposed on the upper surface of the first via 121 in the horizontal direction DR1. The second metal layer 130 may contact each of the upper surface of the first via 121 and the upper surface of the second via 122. In FIG. 1, it is shown that a width W1 in the horizontal direction DR1 of the second metal layer 130 is equal to each of a width in the horizontal direction DR1 of the first via 121 and a width in the horizontal direction DR1 of the second via 122. However, this is merely an example, and the present disclosure is not limited thereto. For example, the second metal layer 130 may include titanium (Ti).

The fourth metal layer 140 may be disposed on an upper surface of the second metal layer 130. That is, the fourth metal layer 140 may be disposed on each of the upper surface of the first via 121 and the upper surface of the second via 122. For example, a portion of the fourth metal layer 140 disposed on the upper surface of the second via 122 may be spaced apart from a portion of the fourth metal layer 140 disposed on the upper surface of the first via 121 in the horizontal direction DR1. The fourth metal layer 140 may be in contact with the upper surface of the second metal layer 130.

For example, on the upper surface of the first via 121, a width W2 in the horizontal direction DR1 of the fourth metal layer 140 may be larger than a width W1 in the horizontal direction DR1 of the second metal layer 130. For example, on the upper surface of the first via 121, each of both opposing sidewalls in the horizontal direction DR1 of the second metal layer 130 may be recessed than each of both opposing sidewalls in the horizontal direction DR1 of the fourth metal layer 140. That is, on each of both opposing sidewalls in the horizontal direction DR1 of the second metal layer 130, at least a portion of the fourth metal layer 140 may overlap with the passivation layer 110 in the vertical direction DR2.

A shape of a portion of the fourth metal layer 140 disposed on the upper surface of the second via 122 may be the same as a shape of a portion of the fourth metal layer 140 disposed on the upper surface of the first via 121. Therefore, the description of the portion of the fourth metal layer 140 disposed on the upper surface of the second via 122 is omitted. For example, the fourth metal layer 140 may include a different metal from a material of the second metal layer 130. For example, the fourth metal layer 140 may include copper (Cu).

The third metal layer 150 may be disposed on the upper surface of the fourth metal layer 140. That is, the third metal layer 150 may be disposed on each of the upper surface of the first via 121 and the upper surface of the second via 122. For example, a portion of the third metal layer 150 disposed on the upper surface of the second via 122 may be spaced apart from a portion of the third metal layer 150 disposed on the upper surface of the first via 121 in the horizontal direction DR1. The third metal layer 150 may contact the upper surface of the fourth metal layer 140.

For example, on the upper surface of the first via 121, a width in the horizontal direction DR1 of the third metal layer 150 may be greater than the width W2 in the horizontal direction DR1 of the fourth metal layer 140. Furthermore, on the upper surface of the first via 121, the width in the horizontal direction DR1 of the third metal layer 150 may be greater than the width W1 in the horizontal direction DR1 of the second metal layer 130. For example, on the upper surface of the first via 121, each of both opposing sidewalls in the horizontal direction DR1 of the second metal layer 130 may be recessed than each of both opposing sidewalls in the horizontal direction DR1 of the third metal layer 150. Furthermore, on the upper surface of the first via 121, each of both opposing sidewalls in the horizontal direction DR1 of the fourth metal layer 140 may be recessed than each of both opposing sidewalls in the horizontal direction DR1 of the third metal layer 150. That is, on each of both opposing sidewalls in the horizontal direction DR1 of the fourth metal layer 140, at least a portion of the third metal layer 150 may overlap the passivation layer 110 in the vertical direction DR2.

A shape of a portion of the third metal layer 150 disposed on the upper surface of the second via 122 may be the same as the shape of a portion of the third metal layer 150 disposed on the upper surface of the first via 121. Therefore, the description of the portion of the third metal layer 150 disposed on the upper surface of the second via 122 is omitted. For example, the third metal layer 150 may include a different metal from a material of each of the second metal layer 130 and the fourth metal layer 140. For example, the third metal layer 150 may include nickel (Ni).

The first metal layer 160 may be disposed on the upper surface of the third metal layer 150. That is, the first metal layer 160 may be disposed on each of the upper surface of the first via 121 and the upper surface of the second via 122. For example, a portion of the first metal layer 160 disposed on the upper surface of the second via 122 may be spaced apart from a portion of the first metal layer 160 disposed on the upper surface of the first via 121 in the horizontal direction DR1. The first metal layer 160 may be in contact with the upper surface of the third metal layer 150.

For example, on the upper surface of the first via 121, a width W3 in the horizontal direction DR1 of the first metal layer 160 may be equal to the width in the horizontal direction DR1 of the third metal layer 150. For example, on the upper surface of the first via 121, the width W3 in the horizontal direction DR1 of the first metal layer 160 may be larger than the width W2 in the horizontal direction DR1 of the fourth metal layer 140. Furthermore, on the upper surface of the first via 121, the width W3 in the horizontal direction DR1 of the first metal layer 160 may be larger than the width W1 in the horizontal direction DR1 of the second metal layer 130.

For example, on the upper surface of the first via 121, each of both opposing sidewalls in the horizontal direction DR1 of the first metal layer 160 may be aligned with each of both opposing sidewalls in the horizontal direction DR1 of the third metal layer 150 in the vertical direction DR2. For example, on the upper surface of the first via 121, each of both opposing sidewalls in the horizontal direction DR1 of the second metal layer 130 may be recessed than each of both opposing sidewalls in the horizontal direction DR1 of the first metal layer 160. Furthermore, on the upper surface of the first via 121, each of both opposing sidewalls in the horizontal direction DR1 of the fourth metal layer 140 may be recessed than each of both opposing sidewalls in the horizontal direction DR1 of the first metal layer 160. That is, on each of both opposing sidewalls in the horizontal direction DR1 of the fourth metal layer 140, at least a portion of the first metal layer 160 may overlap with the passivation layer 110 in the vertical direction DR2.

The shape of the portion of the first metal layer 160 disposed on the upper surface of the second via 122 may be the same as the shape of the portion of the first metal layer 160 disposed on the upper surface of the first via 121. Therefore, the description of the portion of the first metal layer 160 disposed on the upper surface of the second via 122 is omitted. For example, the first metal layer 160 may include a different metal from that of each of the second metal layer 130, the fourth metal layer 140, and the third metal layer 150. For example, the first metal layer 160 may include gold (Au).

Hereinafter, a method for fabricating a semiconductor device according to some embodiments of the present disclosure is described with reference to FIGS. 1 to 8.

FIGS. 2 to 8 are diagrams of intermediate structures corresponding to intermediate steps of a method for fabricating a semiconductor device according to some embodiments of the present disclosure.

Referring to FIG. 2, the substrate 100 may be provided.

For example, the substrate 100 may be a substrate in a form of each of semiconductor chips into which a wafer is divided. In some alternative embodiments, the substrate 100 may be a substrate in a form of a wafer. When the substrate 100 is the substrate in a form of each of semiconductor chips into which a wafer is divided, the substrate 100 may be, for example, a memory semiconductor chip or a logic semiconductor chip.

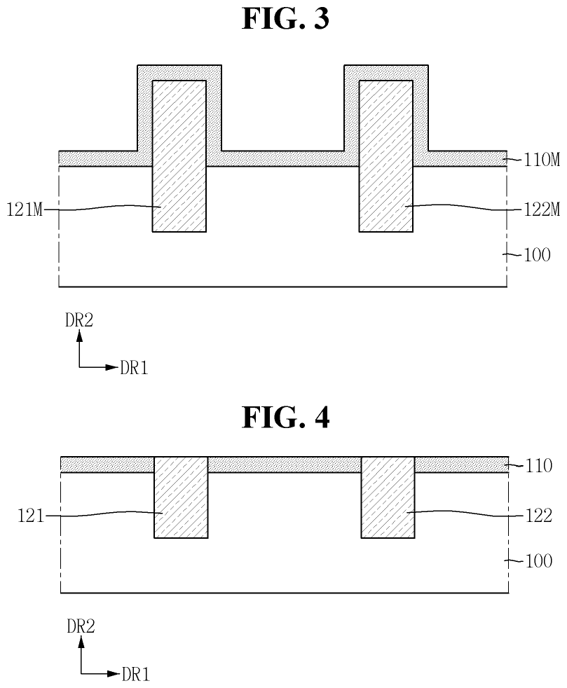

Referring to FIG. 3, a first via material layer 121M and a second via material layer 122M may be formed in the substrate 100. For example, the second via material layer 122M may be spaced from the first via material layer 121M in the horizontal direction DR1. For example, at least a portion of the first via material layer 121M may protrude from the upper surface of the substrate 100 in the vertical direction DR2. Furthermore, at least a portion of the second via material layer 122M may protrude from the upper surface of the substrate 100 in the vertical direction DR2. For example, an upper surface of the first via material layer 121M and an upper surface of the second via material layer 122M may be coplanar with each other. For example, each of the first via material layer 121M and the second via material layer 122M may include a conductive material.

Subsequently, an insulating material layer 110M may be formed on the upper surface of the substrate 100 and cover a protruding portion of each of the first and second via material layers 121M and 122M protruding from the upper surface of the substrate 100. For example, the insulating material layer 110M may be formed conformally. For example, the insulating material layer 110M may be embodied as a nitride film or an oxide film.

Referring to FIG. 4, a planarization process may be performed to etch a portion of the insulating material layer (110M in FIG. 3), a portion of the first via material layer (121M in FIG. 3), and a portion of the second via material layer (122M in FIG. 3). After the planarization process has been performed, the remaining insulating material layer (110M in FIG. 3) may be defined as the passivation layer 110, the remaining first via material layer (121M in FIG. 3) may be defined as the first via 121, and the remaining second via material layer (122M in FIG. 3) may be defined as the second via 122.

After the planarization process has been performed, each of an upper surface of the first via 121 and an upper surface of the second via 122 may be exposed. For example, on the upper surface of the substrate 100, the passivation layer 110 may surround a portion of a sidewall of the first via 121 and a portion of a sidewall of the second via 122. For example, after the planarization process has been performed, an upper surface of the passivation layer 110 may be coplanar with each of the upper surface of the first via 121 and the upper surface of the second via 122. However, the present disclosure is not limited thereto.

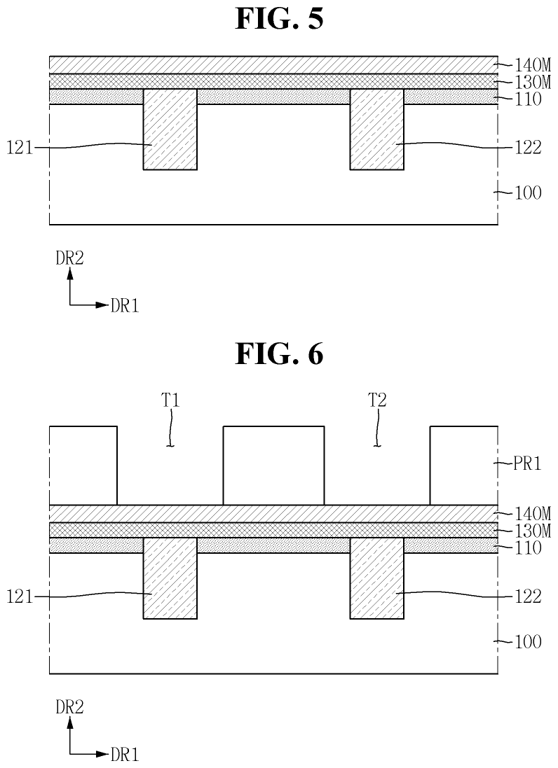

Referring to FIG. 5, the first metal material layer 130M may be formed on the upper surface of the passivation layer 110, the upper surface of the first via 121, and the upper surface of the second via 122. For example, the first metal material layer 130M may contact each of the upper surface of the passivation layer 110, the upper surface of the first via 121, and the upper surface of the second via 122. For example, the first metal material layer 130M may be formed conformally. For example, the first metal material layer 130M may include titanium (Ti).

Subsequently, a second metal material layer 140M may be formed on the upper surface of the first metal material layer 130M. For example, the second metal material layer 140M may contact the upper surface of the first metal material layer 130M. For example, the second metal material layer 140M may be conformally formed. The second metal material layer 140M may include a different metal from that of the first metal material layer 130M. For example, the second metal material layer 140M may include copper (Cu).

Referring to FIG. 6, a photoresist layer may be formed on an upper surface of the second metal material layer 140M. Subsequently, a first trench T1 and a second trench T2 may be formed by performing an exposure process and a development process on the photoresist layer. For example, the second trench T2 may be spaced from the first trench T1 in the horizontal direction DR1. As a result, a photoresist pattern PR1 in which the first trench T1 and the second trench T2 have been defined may be formed on the upper surface of the second metal material layer 140M. For example, the first trench T1 may be formed on the upper surface of the first via 121. Furthermore, the second trench T2 may be formed on the upper surface of the second via 122. For example, an upper surface of the second metal material layer 140M may be exposed through each of the first trench T1 and the second trench T2. A width of the first trench T1 may be greater than a width of the first via 121, and a width of the second trench T2 may be greater than a width of the second via 122.

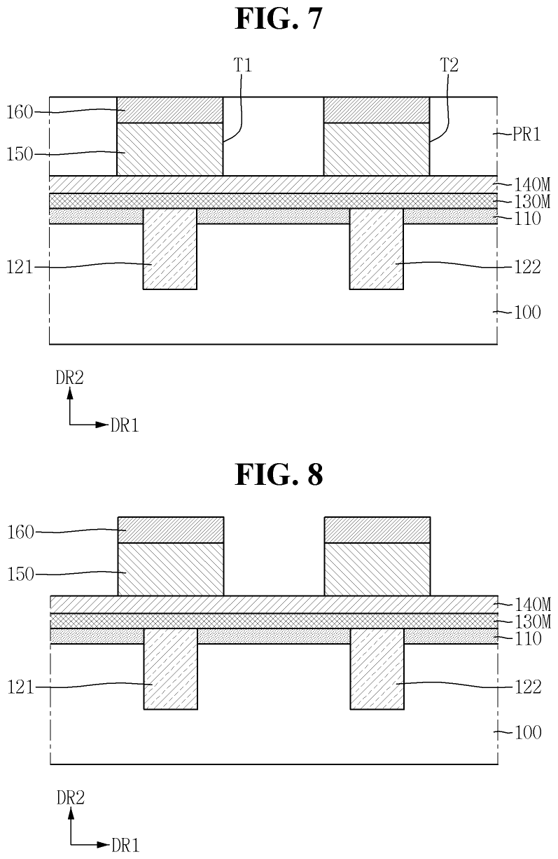

Referring to FIG. 7, the third metal layer 150 may be formed in each of the first trench T1 and the second trench T2. For example, the third metal layer 150 may fill a portion of the first trench T1 and a portion of the second trench T2. That is, a vertical level of the upper surface of the third metal layer 150 formed in the first trench T1 may be lower than a vertical level of the upper surface of the photoresist pattern PR1. Furthermore, the upper surface of the third metal layer 150 formed in the second trench T2 may be lower than a vertical level of the upper surface of the photoresist pattern PR1.

For example, each of both opposing sidewalls in the horizontal direction DR1 of the third metal layer 150 may contact the photoresist pattern PR1. For example, a lower surface of the third metal layer 150 may contact the upper surface of the second metal material layer 140M. The third metal layer 150 may include a different metal from that of each of the first metal material layer 130M and the second metal material layer 140M. For example, the third metal layer 150 may include nickel (Ni).

Subsequently, the first metal layer 160 may be formed on the upper surface of the third metal layer 150 and inside each of the first trench T1 and the second trench T2. For example, on the upper surface of the third metal layer 150, the first metal layer 160 may fill the remaining portion of each of the first trench T1 and the second trench T2. For example, the upper surface of the first metal layer 160 formed in each of the first trench T1 and the second trench T2 may be coplanar with the upper surface of the photoresist pattern PR1. However, the present disclosure is not limited thereto.

For example, each of both opposing sidewalls in the horizontal direction DR1 of the first metal layer 160 may contact the photoresist pattern PR1. For example, a lower surface of the first metal layer 160 may contact the upper surface of the third metal layer 150. The first metal layer 160 may include a different metal from that of each of the first metal material layer 130M, the second metal material layer 140M, and the third metal layer 150. For example, the first metal layer 160 may include gold (Au).

For example, each of the third metal layer 150 and the first metal layer 160 may overlap the second via 122 in the vertical direction DR2 and may overlap the first via 121 in the vertical direction DR2. For example, a portion of the third metal layer 150 and a portion of the first metal layer 160 formed on the upper surface of the second via 122 may be respectively spaced from a portion of the third metal layer 150 and a portion of the first metal layer 160 formed on the upper surface of the first via 121 in the horizontal direction DR1. For example, the width in the horizontal direction DR1 of each of the third metal layer 150 and the first metal layer 160 may be larger than the width in the horizontal direction DR1 of the first via 121. Furthermore, the width in the horizontal direction DR1 of each of the third metal layer 150 and the first metal layer 160 may be larger than the width in the horizontal direction DR1 of the second via 122.

Referring to FIG. 8, the photoresist pattern (PR1 in FIG. 7) may be removed. As a result, on each of both opposing sidewalls in the horizontal direction DR1 of each of the third metal layer 150 and the first metal layer 160, the upper surface of the second metal material layer 140M may be exposed.

Referring to FIG. 1, a portion of the first metal material layer (130M in FIG. 8) and a portion of the second metal material layer (140M in FIG. 8) may be etched using an etching composition. After the etching process using the etching composition has been completed, each of the first metal material layer (130M in FIG. 8) and the second metal material layer (140M in FIG. 8) may remain under the third metal layer 150. For example, after the etching process using the etching composition has been completed, the remaining first metal material layer (130M in FIG. 8) may be defined as the second metal layer 130, and the remaining second metal material layer (140M in FIG. 8) may be defined as the fourth metal layer 140. That is, the second metal layer 130 may include titanium (Ti), and the fourth metal layer 140 may include copper (Cu).

For example, the width W3 in the horizontal direction DR1 of the third metal layer 150 and the width W3 in the horizontal direction DR1 of the first metal layer 160 may be equal to each other. For example, the width W2 in the horizontal direction DR1 of the fourth metal layer 140 may be smaller than each of the width W3 in the horizontal direction DR1 of the third metal layer 150 and the width W3 in the horizontal direction DR1 of the first metal layer 160. For example, the width W1 in the horizontal direction DR1 of the second metal layer 130 may be smaller than the width W2 in the horizontal direction DR1 of the fourth metal layer 140.

For example, each of both opposing sidewalls in the horizontal direction DR1 of the fourth metal layer 140 may be recessed than each of both opposing sidewalls in the horizontal direction DR1 of the third metal layer 150. Furthermore, each of both opposing sidewalls in the horizontal direction DR1 of the fourth metal layer 140 may be recessed than each of both opposing sidewalls in the horizontal direction DR1 of the first metal layer 160. For example, each of both opposing sidewalls in the horizontal direction DR1 of the second metal layer 130 may be recessed than each of both opposing sidewalls in the horizontal direction DR1 of the fourth metal layer 140. Through this fabricating process, the semiconductor device as shown in FIG. 1 may be fabricated.

The etching composition may selectively etch the second metal layer 130 including titanium (Ti) and the third metal layer 150 including copper (Cu). For example, the etching composition may include water, an oxidizer, a Cu etch inhibitor, a hydrogen peroxide stabilizer (H₂O₂ stabilizer), a first chelating agent, a second chelating agent, and an alkali.

For example, pH of the etching composition may be in a range 8 to 9.5. For example, water may be used as a solvent of the etching composition. For example, the oxidizer may include hydrogen peroxide (H₂O₂). For example, the oxidizer may be included at a content of 10 wt % to 35 wt % based on a total weight of the etching composition. For example, the copper etch inhibitor may include at least one selected from the group including metal imidazole, pyrazole, tolytriazole, and benzotriazole. However, the present disclosure is not limited thereto. For example, the hydrogen peroxide stabilizer (H₂O₂ stabilizer) may include at least one selected from the group including ammonium acetate, potassium acetate, and sodium acetate. However, the present disclosure is not limited thereto.

For example, the first chelating agent may include a hydroxy phosphonic acid compound. For example, the hydroxy phosphonic acid compound may include one or more types selected from the group including pamidronic acid, alendronic acid, risedronic acid, zoledronic acid, and etidronic acid. For example, the hydroxy phosphonic acid compound may be included at a content of 0.01 wt % to 1 wt % based on the total weight of the etching composition.

For example, the second chelating agent may include a polyamine compound. For example, the polyamine compound may include at least one selected from the group including diethyene triamine, triethylene tetramine, and pentaethylene hexamine. For example, the polyamine compound may be included at a content of 0.01 wt % to 1 wt % based on the total weight of the etching composition.

For example, the alkali may include at least one selected from the group including potassium hydroxide, sodium hydroxide, ammonium hydroxide, and tetramethyl ammonium hydroxide. For example, the alkali may be included at a content of 0.01 wt % to 1 wt % based on the total weight of the etching composition.

For example, the etching composition may be prepared by reacting each of the hydroxy phosphonic acid compound as the first chelating agent and the polyamine compound as the second chelating agent with water, and then adding the hydrogen peroxide (H₂O₂) as the oxidizer to the water.

TABLE 1

| | | | hydroxy phosphonic | | polyamine | | | | | | |
|---|---|---|---|---|---|---|---|---|---|---|---|
| | oxidizer | | acid compounds | | compounds | | alkali | | | | Ti |
| | | content | | content | | content | | content | | Cu | etching |
| | Material | (wt %) | material | (wt %) | material | (wt %) | material | (wt %) | pH | discoloration | amount |
| C1 | H₂O₂ | 30 | | | | | KOH | 2.0 | 8.0 | ◯ | Large |
| C2 | H₂O₂ | 20 | | | | | KOH | 2.0 | 8.8 | ◯ | Large |
| C3 | H₂O₂ | 15 | | | | | KOH | 2.0 | 9.5 | ◯ | Large |
| C4 | H₂O₂ | 30 | | | DETA | 0.01 | KOH | 2.5 | 8.0 | ◯ | Large |
| C5 | H₂O₂ | 30 | EDA | 0.01 | | | KOH | 2.0 | 8.0 | X | Large |
| C6 | H₂O₂ | 30 | EDA | 0.01 | DETA | 0.001 | KOH | 2.0 | 9.5 | X | Medium |
| C7 | H₂O₂ | 30 | EDA | 0.001 | DETA | 0.01 | KOH | 2.5 | 8.0 | X | Medium |
| E1 | H₂O₂ | 30 | EDA | 0.01 | DETA | 0.01 | KOH | 2.5 | 8.8 | X | Small |

Hereinafter, with reference to Table 1, an effect of the etching composition used in the method for fabricating the semiconductor device according to some embodiments of the present disclosure is described. Table 1 shows first to seventh Comparative Examples C1 to C7 and an Experimental Example E1 based on the pH of the etching composition, and a material and a content of each of the oxidizer, the hydroxy phosphonic acid compound, the polyamine compound, and the alkali included in the etching composition.

In the Table 1, the hydroxy phosphonic acid compound may be used as the first chelating agent, and the polyamine compound may be used as the second chelating agent. In the Table 1, the oxidizer employs hydrogen peroxide (H₂O₂), the hydroxy phosphonic acid compound employs etidronic acid (EDA), the polyamine compound employs ethylene triamine (DETA), and the alkali employs potassium hydroxide (KOH). In the Table 1, the pH of the etching composition is in a range of 8 to 9.5.

In the Table 1, the first to seventh Comparative Examples C1 to C7 represent example etching compositions for comparison with the etching composition of the present disclosure, and the Experimental Example E1 represents the etching composition of the present disclosure.

In each of the first to third Comparative Examples C1, C2, and C3, the etching composition is free of the hydroxy phosphonic acid compound as the first chelating agent, and the polyamine compound as the second chelating agent. It may be identified that in each of the first to third Comparative Examples C1, C2, and C3, when the etching composition does not include the hydroxy phosphonic acid compound and the polyamine compound, copper (Cu) is discolored, and the etching amount of titanium (Ti) is large.

In the fourth Comparative Example C4, the etching composition does not include the hydroxy phosphonic acid compound as the first chelating agent. Furthermore, in the fourth Comparative Example C4, the etching composition includes the polyamine compound as the second chelating agent. In this case, diethyene triamine (DETA) is used as the polyamine compound. In the fourth Comparative Example C4, diethyene triamine (DETA) has a content of 0.01 wt % based on the total weight of the etching composition. It may be identified that in the fourth Comparative Example C4, when the etching composition does not include the hydroxy phosphonic acid compound but includes diethyene triamine (DETA), the copper (Cu) is discolored, and the etching amount of titanium (Ti) is large.

In the fifth Comparative Example C5, the etching composition includes the hydroxy phosphonic acid compound as the first chelating agent. In this case, etidronic acid (EDA) is used as the hydroxy phosphonic acid compound. Furthermore, in the fifth Comparative Example C5, the etching composition does not include the polyamine compound as the second chelating agent. In the fifth Comparative Example C5, etidronic acid (EDA) has a content of 0.01 wt % based on the total weight of the etching composition. It may be identified that in the fifth Comparative Example C5, when the etching composition includes etidronic acid (EDA) and does not include the polyamine compound, copper (Cu) is not discolored, but the etching amount of titanium (Ti) is large.

In the sixth Comparative Example C6, the etching composition includes the hydroxy phosphonic acid compound as the first chelating agent. In this case, etidronic acid (EDA) is used as the hydroxy phosphonic acid compound. Furthermore, in the sixth Comparative Example C6, the etching composition includes the polyamine compound as the second chelating agent. In this case, diethyene triamine (DETA) is used as the polyamine compound. However, in the sixth Comparative Example C6, etidronic acid (EDA) has a content of 0.01 wt % based on the total weight of the etching composition, and diethylene triamine (DETA) has a content of 0.001 wt % based on the total weight of the etching composition. It may be identified that in the sixth Comparative Example C6, when diethyene triamine (DETA) has a content of 0.001 wt % based on the total weight of etching composition, copper (Cu) is not discolored, but the etching amount of titanium (Ti) is medium.

In the seventh Comparative Example C7, the etching composition includes the hydroxy phosphonic acid compound as the first chelating agent. In this case, etidronic acid (EDA) is used as the hydroxy phosphonic acid compound. Furthermore, in the seventh Comparative Example C7, the etching composition includes the polyamine compound as the second chelating agent. In this case, diethyene triamine (DETA) is used as the polyamine compound. However, in the seventh Comparative Example C7, etidronic acid (EDA) has a content of 0.001 wt % based on the total weight of the etching composition, and diethylene triamine (DETA) has a content of 0.01 wt % based on the total weight of the etching composition. It may be identified that in the seventh Comparative Example C7, when etidronic acid (EDA) has a content of 0.001 wt % based on the total weight of etching composition, copper (Cu) is not discolored, but the etching amount of titanium (Ti) is medium.

Conventionally, in a structure in which a metal layer including titanium (Ti), a metal layer including copper (Cu), and a metal layer including gold (Au) are stacked, a process of selectively etching the metal layer including titanium (Ti) using the etching composition includes hydrogen peroxide (H₂O₂) as the oxidizer is performed. In this case, the hydrogen peroxide (H₂O₂) may react with gold (Au) to produce oxygen (O₂). The produced oxygen (O₂) may oxidize the metal layer including copper (Cu), thereby causing discoloration of the metal layer including copper (Cu). Furthermore, the oxygen (O₂) may increase the etching amount of the metal layer including titanium (Ti), thereby reducing a stability of the metal layer including titanium (Ti).

In Experimental Example E1, the etching composition includes the hydroxy phosphonic acid compound as the first chelating agent, and the polyamine compound as the second chelating agent. In Experimental Example E1, the hydroxy phosphonic acid compound employs etidronic acid (EDA), and the polyamine compound employs diethyene triamine (DETA). In Experimental Example E1, etidronic acid (EDA) has a content of 0.01 wt % based on the total weight of the etching composition, and diethylene triamine (DETA) has a content of 0.01 wt % based on the total weight of the etching composition. It may be identified that in Experimental Example E1, copper (Cu) is not discolored, and the etching amount of titanium (Ti) is small.

That is, when the etching composition includes both etidronic acid (EDA) as the first chelating agent and diethyene triamine (DETA) as the second chelating agent, etidronic acid (EDA) has a content of 0.01 wt % based on the total weight of the etching composition, and diethylene triamine (DETA) has a content of 0.01 wt % based on the total weight of the etching composition, the discoloration of copper (Cu) may be prevented, and the etching amount of titanium (Ti) may be reduced.

In the method for fabricating a semiconductor device according to some embodiments of the present disclosure, in the structure in which the second metal layer 130 including titanium (Ti), the fourth metal layer 140 including copper (Cu), and the first metal layer 160 including gold (Au) are stacked, the second metal layer 130 including titanium (Ti) may be selectively etched using the etching composition including the hydroxy phosphonic acid compound as the first chelating agent, and the polyamine compound as the second chelating agent. The hydroxy phosphonic acid compound and the polyamine compound included in the etching composition have coordinate bonds with the first metal layer 160 including gold (Au), such that hydrogen peroxide (H₂O₂) may be prevented from reacting with gold (Au), thereby preventing oxygen (O₂) from being produced. Thus, the method for fabricating the semiconductor device according to some embodiments of the present disclosure may prevent the fourth metal layer 140 including copper (Cu) from being discolored, and may reduce the etching amount of the second metal layer 130 including titanium (Ti), such that the stability of the second metal layer 130 including titanium (Ti) may be improved.

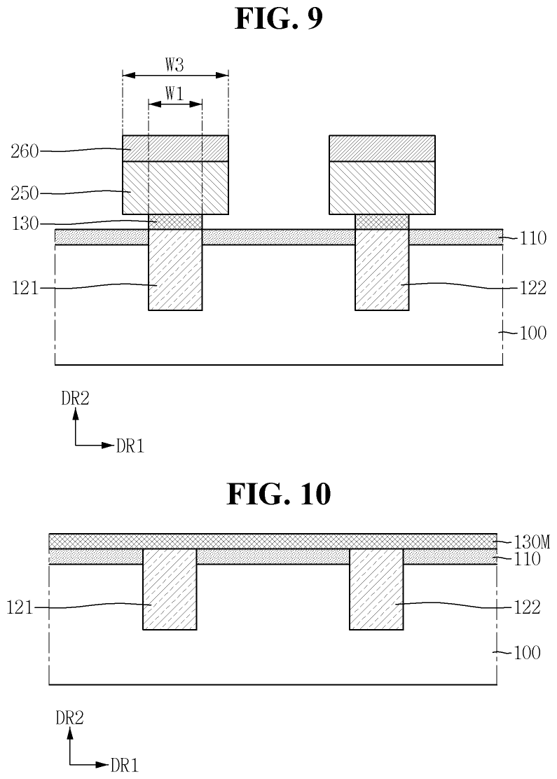

Hereinafter, with reference to FIG. 9, a semiconductor device fabricated by a method for fabricating a semiconductor device according to further some embodiments of the present disclosure is described. Following description focuses on differences thereof from the semiconductor device as shown in FIG. 1.

FIG. 9 is a diagram for illustrating a semiconductor device fabricated by a method for fabricating a semiconductor device according to further some embodiments of the present disclosure.

Referring to FIG. 9, compared to the semiconductor device as shown in FIG. 1, the semiconductor device fabricated by the method for fabricating a semiconductor device according to further some embodiments of the present disclosure is free of the fourth metal layer (140 in FIG. 1).

For example, the third metal layer 250 may be disposed on the upper surface of the second metal layer 130. That is, the third metal layer 250 may be disposed on each of the upper surface of the first via 121 and the upper surface of the second via 122. For example, a portion off the third metal layer 250 disposed on the upper surface of the second via 122 may be spaced apart from a portion of the third metal layer 250 disposed on the upper surface of the first via 121 in the horizontal direction DR1. The third metal layer 250 may be in contact with the upper surface of the second metal layer 130.

For example, on the upper surface of the first via 121, the width in the horizontal direction DR1 of the third metal layer 250 may be greater than the width W1 in the horizontal direction DR1 of the second metal layer 130. For example, on the upper surface of the first via 121, each of both opposing sidewalls in the horizontal direction DR1 of the second metal layer 130 may be recessed than each of both opposing sidewalls in the horizontal direction DR1 of the third metal layer 250. The shape of the portion of the third metal layer 250 disposed on the upper surface of the second via 122 may be the same as the shape of the portion of the third metal layer 250 disposed on the upper surface of the first via 121. Therefore, the description of the portion of the third metal layer 250 disposed on the upper surface of the second via 122 is omitted. For example, the third metal layer 250 may include a different metal from that of the second metal layer 130. For example, the third metal layer 250 may include nickel (Ni) or copper (Cu).

A first metal layer 260 may be disposed on the upper surface of the third metal layer 250. That is, the first metal layer 260 may be disposed on each of the upper surface of the first via 121 and the upper surface of the second via 122. For example, the portion of the first metal layer 260 disposed on the upper surface of the second via 122 may be spaced apart from the portion of the first metal layer 260 disposed on the upper surface of the first via 121 in the horizontal direction DR1. The first metal layer 260 may be in contact with the upper surface of the third metal layer 250.

For example, on the upper surface of the first via 121, the width W3 in the horizontal direction DR1 of the first metal layer 260 may be equal to the width in the horizontal direction DR1 of the third metal layer 250. For example, on the upper surface of the first via 121, the width W3 in the horizontal direction DR1 of the first metal layer 260 may be larger than the width W1 in the horizontal direction DR1 of the second metal layer 130. For example, on the upper surface of the first via 121, each of both opposing sidewalls in the horizontal direction DR1 of the first metal layer 260 may be vertically aligned with each of both opposing sidewalls in the horizontal direction DR1 of the third metal layer 250.

For example, on the upper surface of the first via 121, each of both opposing sidewalls in the horizontal direction DR1 of the second metal layer 130 may be recessed than each of both opposing sidewalls in the horizontal direction DR1 of the first metal layer 260. The shape of the portion of the first metal layer 260 disposed on the upper surface of the second via 122 may be the same as the shape of the portion of the first metal layer 260 disposed on the upper surface of the first via 121. Therefore, the description of the portion of the first metal layer 260 disposed on the upper surface of the second via 122 is omitted. For example, the first metal layer 260 may include a different metal from that of each of the second metal layer 130 and the third metal layer 250. For example, the first metal layer 260 may include gold (Au).

Hereinafter, with reference to FIGS. 9 to 13, a method for fabricating a semiconductor device according to further some embodiments of the present disclosure is described. Following description focuses on differences thereof from the method for fabricating the semiconductor device as shown in FIGS. 2 to 8.

Referring to FIG. 10, after performing the fabricating process as shown in FIGS. 2 to 4, the first metal material layer 130M may be formed on each of the upper surface of the passivation layer 110, the upper surface of the first via 121, and the upper surface of the second via 122. For example, the first metal material layer 130M may contact each of the upper surface of the passivation layer 110, the upper surface of the first via 121, and the upper surface of the second via 122. For example, the first metal material layer 130M may be formed conformally. For example, the first metal material layer 130M may include titanium (Ti).

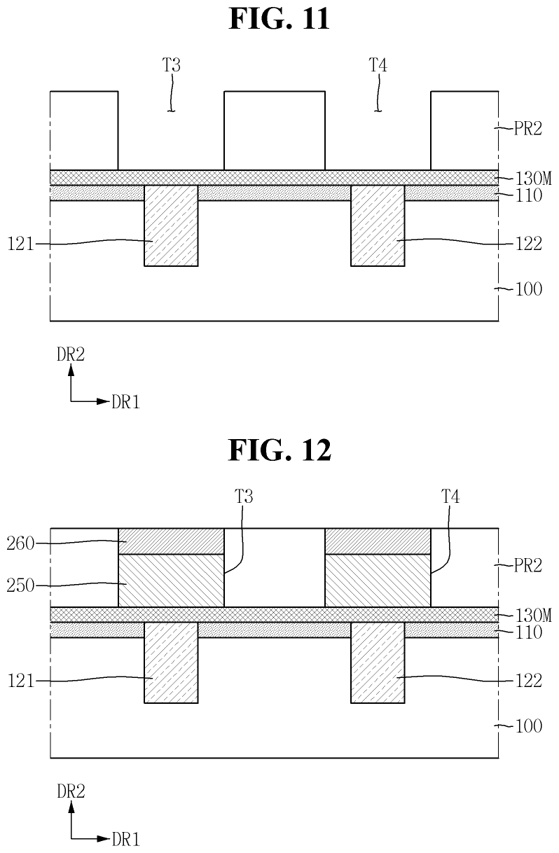

Referring to FIG. 11, a photoresist layer may be formed on the upper surface of the first metal material layer 130M. Next, an exposure process and a development process may be performed on the photoresist layer to form a third trench T3 and a fourth trench T4. For example, the fourth trench T4 may be spaced apart from the third trench T3 in the horizontal direction DR1. As a result, a photoresist pattern PR2 in which the third trench T3 and the fourth trench T4 have been formed may be formed on the upper surface of the first metal material layer 130M. For example, the third trench T3 may be formed on the upper surface of the first via 121. Furthermore, the fourth trench T4 may be formed on the upper surface of the second via 122. For example, the upper surface of the first metal material layer 130M may be exposed through each of the third trench T3 and fourth trench T4. A width of the third trench T3 may be greater than a width of the first via 121, and a width of the fourth trench T4 may be greater than a width of the second via 122.

Referring to FIG. 12, a third metal layer 250 may be formed in each of the third trench T3 and the fourth trench T4. For example, the third metal layer 250 may fill a portion of the third trench T3 and a portion of the fourth trench T4. For example, each of both opposing sidewalls in the horizontal direction DR1 of the third metal layer 250 may contact the photoresist pattern PR2. For example, a lower surface of the third metal layer 250 may contact the upper surface of the first metal material layer 130M. The third metal layer 250 may include a different metal from that of the first metal material layer 130M. For example, the third metal layer 250 may include nickel (Ni) or copper (Cu).

Subsequently, the first metal layer 260 may be formed on the upper surface of the third metal layer 250 and in each of the third trench T3 and the fourth trench T4. For example, on the upper surface of the third metal layer 250, the first metal layer 260 may fill the remaining portions of each of the third trench T3 and the fourth trench T4. For example, each of both opposing sidewalls in the horizontal direction DR1 of the first metal layer 260 may contact the photoresist pattern PR2. For example, a lower surface of the first metal layer 260 may contact the upper surface of the third metal layer 250. The first metal layer 260 may include a different metal from that of each of the first metal material layer 130M and the third metal layer 250. For example, the first metal layer 260 may include gold (Au).

For example, each of the third metal layer 250 and the first metal layer 260 may overlap the first via 121 in the vertical direction DR2 and may overlap the second via 122 in the vertical direction DR2. For example, a portion of the third metal layer 250 and a portion of the first metal layer 260 formed on the upper surface of the second via 122 may be respectively spaced from a portion of the third metal layer 250 and a portion of the first metal layer 260 formed on the upper surface of the first via 121 in the horizontal direction DR1. For example, the width in the horizontal direction DR1 of each of the third metal layer 250 and the first metal layer 260 may be larger than the width in the horizontal direction DR1 of the first via 121. Furthermore, the width in the horizontal direction DR1 of each of the third metal layer 250 and the first metal layer 260 may be larger than the width in the horizontal direction DR1 of the second via 122.

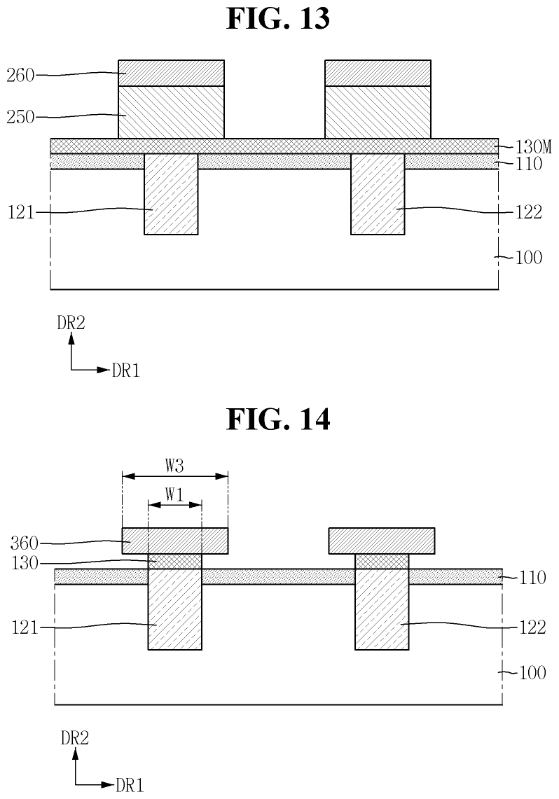

Referring to FIG. 13, the photoresist pattern (PR2 in FIG. 12) may be removed. As a result, on each of both opposing sidewalls of the third metal layer 250 and the first metal layer 260 in the horizontal direction DR1, the upper surface of the first metal material layer 130M may be exposed.

Referring to FIG. 9, a portion of the first metal material layer (130M in FIG. 13) may be etched using the etching composition according to some embodiments of the present disclosure. After the etching process using the etching composition has been completed, the first metal material layer (130M in FIG. 13) may remain under the third metal layer 250. For example, after the etching process using the etching composition has been completed, the remaining first metal material layer 130M in FIG. 13 may be defined as the second metal layer 130. That is, the second metal layer 130 may include titanium (Ti).

For example, the width in the horizontal direction DR1 of the third metal layer 250 and the width W3 in the horizontal direction DR1 of the first metal layer 260 may be equal to each other. For example, the width W1 in the horizontal direction DR1 of the second metal layer 130 may be smaller than each of the width in the horizontal direction DR1 of the third metal layer 250 and the width W3 in the horizontal direction DR1 of the first metal layer 260. For example, each of both opposing sidewalls in the horizontal direction DR1 of the second metal layer 130 may be recessed than each of both opposing sidewalls in the horizontal direction DR1 of the third metal layer 250. Furthermore, each of both opposing sidewalls in the horizontal direction DR1 of the second metal layer 130 may be recessed than each of both opposing sidewalls in the horizontal direction DR1 of the first metal layer 260. Through this fabricating process, the semiconductor device as shown in FIG. 9 may be fabricated.

Hereinafter, with reference to FIG. 14, a semiconductor device fabricated by a method for fabricating a semiconductor device according to still further some embodiments of the present disclosure is described. Following description focuses on differences thereof from the semiconductor device as shown in FIG. 1.

FIG. 14 is a diagram for illustrating a semiconductor device fabricated by a method for fabricating a semiconductor device according to still further some embodiments of the present disclosure.

Referring to FIG. 14, compared to the semiconductor device as shown in FIG. 1, the semiconductor device fabricated by the method for fabricating a semiconductor device according to still further some embodiments of the present disclosure is free of the fourth metal layer (140 in FIG. 1) and the third metal layer (150 in FIG. 1).

For example, a first metal layer 360 may be disposed on the upper surface of the second metal layer 130. That is, the first metal layer 360 may be disposed on each of the upper surface of the first via 121 and the upper surface of the second via 122. For example, a portion of the first metal layer 360 disposed on the upper surface of the second via 122 may be spaced apart from a portion of the first metal layer 360 disposed on the upper surface of the first via 121 in the horizontal direction DR1. The first metal layer 360 may be in contact with the upper surface of the second metal layer 130.

For example, on the upper surface of the first via 121, the width W3 in the horizontal direction DR1 of the first metal layer 360 may be larger than the width W1 in the horizontal direction DR1 of the second metal layer 130. For example, on the upper surface of the first via 121, each of both opposing sidewalls in the horizontal direction DR1 of the second metal layer 130 may be recessed than each of both opposing sidewalls in the horizontal direction DR1 of the first metal layer 360. A shape of the portion of the first metal layer 360 disposed on the upper surface of the second via 122 may be the same as a shape of the portion of the first metal layer 360 disposed on the upper surface of the first via 121. Therefore, the description of the portion of the first metal layer 360 disposed on the upper surface of the second via 122 is omitted. For example, the first metal layer 360 may include a different metal from that of the second metal layer 130. For example, the first metal layer 360 may include gold (Au).

Hereinafter, with reference to FIGS. 14 to 18, a method for fabricating a semiconductor device according to still further some embodiments of the present disclosure is described. Following description focuses on differences thereof from the method for fabricating the semiconductor device as shown in FIGS. 2 to 8.

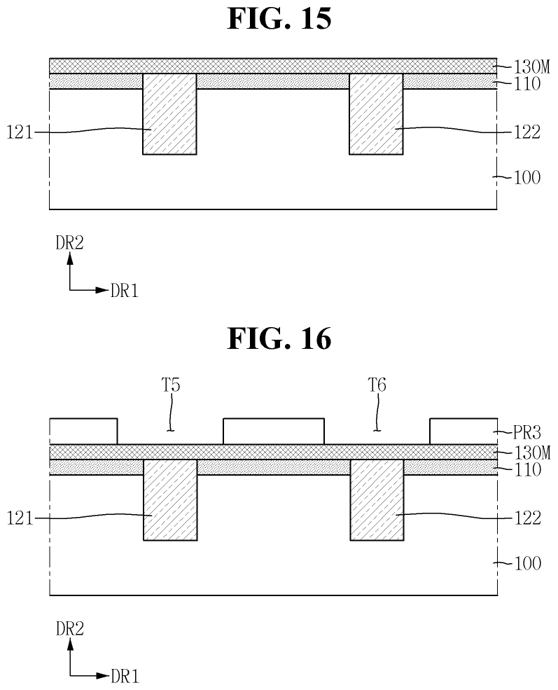

Referring to FIG. 15, after performing the fabricating process shown in FIGS. 2 to 4, the first metal material layer 130M may be formed on each of the upper surface of the passivation layer 110, the upper surface of the first via 121, and the upper surface of the second via 122. For example, the first metal material layer 130M may contact each of the upper surface of the passivation layer 110, the upper surface of the first via 121, and the upper surface of the second via 122. For example, the first metal material layer 130M may be formed conformally. For example, the first metal material layer 130M may include titanium (Ti).

Referring to FIG. 16, a photoresist layer may be formed on the upper surface of the first metal material layer 130M. Next, an exposure process and a development process on the photoresist layer may be performed to form a fifth trench T5 and a sixth trench T6. For example, the sixth trench T6 may be spaced apart from the fifth trench T5 in the horizontal direction DR1. As a result, a photoresist pattern PR3 in which the fifth trench T5 and the sixth trench T6 have been formed may be formed on the upper surface of the first metal material layer 130M. For example, the fifth trench T5 may be formed on the upper surface of the first via 121. Furthermore, the sixth trench T6 may be formed on the upper surface of the second via 122. For example, the upper surface of the first metal material layer 130M may be exposed through each of the fifth trench T5 and the sixth trench T6. A width of the fifth trench T5 may be greater than a width of the first via 121, and a width of the sixth trench T6 may be greater than a width of the second via 122.

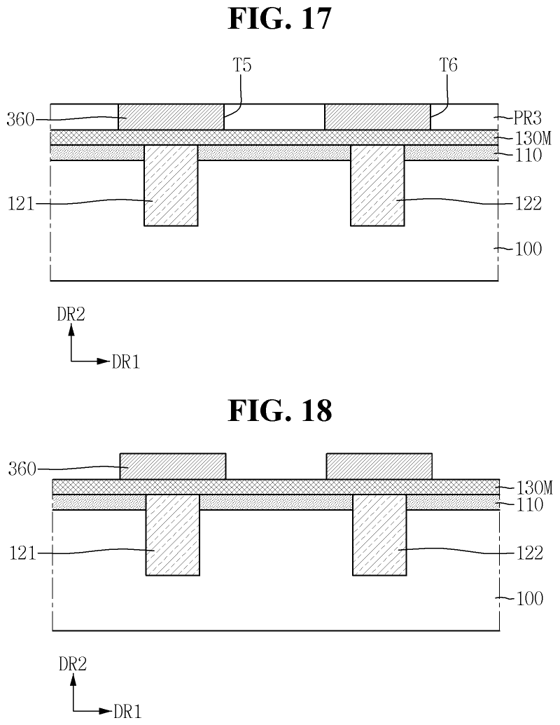

Referring to FIG. 17, the first metal layer 360 may be formed in each of the fifth trench T5 and the sixth trench T6. For example, the first metal layer 360 may fill the fifth trench T5 and the sixth trench T6. For example, each of both opposing sidewalls in the horizontal direction DR1 of the first metal layer 360 may contact the photoresist pattern PR3. For example, a lower surface of the first metal layer 360 may contact the upper surface of the first metal material layer 130M. The first metal layer 360 may include a different metal from that of the first metal material layer 130M. For example, the first metal layer 360 may include gold (Au). For example, the upper surface of the first metal layer 360 may be coplanar with an upper surface of the photoresist pattern PR3.

For example, the first metal layer 360 may overlap each of the first via 121 and the second via 122 in the vertical direction DR2. For example, the portion of the first metal layer 360 formed on the upper surface of the second via 122 may be spaced from a portion of the first metal layer 360 formed on the upper surface of the first via 121 in the horizontal direction DR1. For example, the width in the horizontal direction DR1 of the first metal layer 360 may be larger than the width in the horizontal direction DR1 of the first via 121. Furthermore, the width in the horizontal direction DR1 of the first metal layer 360 may be larger than the width in the horizontal direction DR1 of the second via 122.

Referring to FIG. 18, the photoresist pattern (PR3 in FIG. 17) may be removed. As a result, on each of both opposing sidewalls in the horizontal direction DR1 of the first metal layer 360, the upper surface of the first metal material layer 130M may be exposed.

Referring to FIG. 14, a portion of the first metal material layer (130M in FIG. 18) may be etched using the etching composition according to some embodiments of the present disclosure. After the etching process using the etching composition has been completed, the first metal material layer (130M in FIG. 18) may remain under the first metal layer 360. For example, after the etching process using the etching composition has been completed, the remaining first metal material layer (130M in FIG. 18) may be defined as the second metal layer 130. That is, the second metal layer 130 may include titanium (Ti).

For example, the width W1 in the horizontal direction DR1 of the second metal layer 130 may be smaller than the width W3 in the horizontal direction DR1 of the first metal layer 360. For example, each of both opposing sidewalls in the horizontal direction DR1 of the second metal layer 130 may be recessed than each of both opposing sidewalls in the horizontal direction DR1 of the first metal layer 360. Through this fabricating process, the semiconductor device as shown in FIG. 14 may be fabricated.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

1. A method for fabricating a semiconductor device, the method comprising:
forming a first metal material layer on an upper surface of a substrate, the first metal material layer including titanium (Ti);
forming a photoresist pattern in which a trench is formed on an upper surface of the first metal material layer;
forming a first metal layer including gold (Au) in the trench;
removing the photoresist pattern; and
etching a portion of the first metal material layer using an etching composition, such that a remaining portion of the first metal material layer under the first metal layer after etching becomes a second metal layer,
wherein the etching composition includes water, an oxidizer, a first chelating agent including a hydroxy phosphonic acid compound, a second chelating agent including a polyamine compound, and an alkali.

2. The method of claim 1, wherein the etching composition is prepared by:
after reacting the first chelating agent and the second chelating agent with the water, adding the oxidizer to the water.

3. The method of claim 1, wherein the oxidizer includes hydrogen peroxide (H₂O₂).

4. The method of claim 1, wherein the hydroxy phosphonic acid compound includes one or more selected from the group consisting of pamidronic acid, alendronic acid, risedronic acid, zoledronic acid, and etidronic acid.

5. The method of claim 1, wherein the polyamine compound includes one or more selected from the group consisting of diethylene triamine, triethylene tetramine, and pentaethylene hexamine.

6. The method of claim 1, wherein the alkali includes one or more selected from the group consisting of potassium hydroxide, sodium hydroxide, ammonium hydroxide, and tetramethyl ammonium hydroxide.

7. The method of claim 1, wherein a width in a horizontal direction of the second metal layer is smaller than a width in the horizontal direction of the first metal layer, and
wherein each of both opposing sidewall in the horizontal direction of the second metal layer is recessed than each of both opposing sidewalls in the horizontal direction of the first metal layer.

8. The method of claim 1, further comprising:
forming a third metal layer in the trench, the third metal layer including a metal different from a metal of each of the first metal material layer and the first metal layer,
wherein the first metal layer is formed in the trench to be in contact with an upper surface of the third metal layer.

9. The method of claim 8, wherein the forming the third metal layer comprises:
forming the third metal layer such that the third metal layer is in contact with the upper surface of the first metal material layer.

10. The method of claim 1, further comprising:
before the forming the photoresist pattern, forming a second metal material layer being in contact with the upper surface of the first metal material layer,
wherein the second metal material layer includes a metal different from a metal of each of the first metal material layer and the first metal layer.

11. The method of claim 10, wherein the etching by the etching composition further comprises:
etching a portion of the second metal material layer, such that a remaining portion of the second metal material layer under the second metal layer after etching becomes a fourth metal layer.

12. The method of claim 11, wherein a width in a horizontal direction of the fourth metal layer is smaller than a width in the horizontal direction of the first metal layer,
wherein the width in the horizontal direction of the fourth metal layer is greater than a width in the horizontal direction of the second metal layer,
wherein each of both opposing sidewalls in the horizontal direction of the fourth metal layer is recessed than each of both opposing sidewalls in the horizontal direction of the first metal layer, and
wherein each of both opposing sidewalls in the horizontal direction of the second metal layer is recessed than each of both opposing sidewalls in the horizontal direction of the fourth metal layer.

13. A method for fabricating a semiconductor device, the method comprising:
forming a via in a substrate, at least a portion of the via protruding in a vertical direction from an upper surface of the substrate;
forming a passivation layer on the upper surface of the substrate, the passivation layer surrounding a portion of a sidewall of the via;
forming a first metal material layer on an upper surface of the passivation layer and an upper surface of the via, the first metal material layer including titanium (Ti);
forming a first metal layer on an upper surface of the first metal material layer, the first metal layer including gold (Au); and
etching a portion of a sidewall of the first metal material layer using an etching composition, such that a remaining portion of the first metal material layer under the first metal layer after etching becomes a second metal layer,
wherein a width in a horizontal direction of the second metal layer is smaller than a width in the horizontal direction of the first metal layer,
wherein each of both opposing sidewalls in the horizontal direction of the second metal layer is recessed than each of both opposing sidewalls in the horizontal direction of the first metal layer, and
wherein the etching composition includes an oxidizer including hydrogen peroxide (H₂O₂), a first chelating agent including a hydroxy phosphonic acid compound, a second chelating agent including a polyamine compound, and an alkali.

14. The method of claim 13, wherein the forming the first metal layer comprises:
forming a photoresist pattern in which a trench is formed on the upper surface of the first metal material layer; and
forming the first metal layer in the trench.

15. The method of claim 13, wherein the hydroxy phosphonic acid compound is included at a content of 0.01 wt % to 1 wt % based on a total weight of the etching composition.

16. The method of claim 13, wherein the polyamine compound is included at a content of 0.01 wt % to 1 wt % based on a total weight of the etching composition.

17. The method of claim 13, wherein the oxidizer is included at a content of 10 wt % to 35 wt % based on a total weight of the etching composition.

18. The method of claim 13, wherein pH of the etching composition is in a range of 8 to 9.5.

19. The method of claim 13, wherein the forming the first metal layer comprises,
forming the first metal layer such that the first metal layer is in contact with the upper surface of the first metal material layer.

20. A method for fabricating a semiconductor device, the method comprising:
forming a via in a substrate, at least a portion of the via protruding in a vertical direction from an upper surface of the substrate;
forming a passivation layer on the upper surface of the substrate, the passivation layer surrounding a portion of a sidewall of the via;
forming a first metal material layer on an upper surface of the passivation layer and an upper surface of the via, the first metal material layer including titanium (Ti);
forming a second metal material layer being in contact with an upper surface of the first metal material layer, the second metal material layer including a metal different from a metal of the first metal material layer;
forming a photoresist pattern in which a trench is formed on the upper surface of the first metal material layer;
forming a third metal layer in the trench, the third metal layer including a metal different from each of the metal of the first metal material layer and the metal of the second metal material layer;
forming a first metal layer being in contact with an upper surface of the third metal layer in the trench, the first metal layer including gold (Au);
removing the photoresist pattern; and
etching each of a portion of the first metal material layer and a portion of the second metal material layer using an etching composition, such that a remaining portion of the second metal material layer under the third metal layer after etching becomes a fourth metal layer and a remaining portion of the first metal material layer under the fourth metal layer after etching becomes a second metal layer,
wherein a width in a horizontal direction of the fourth metal layer is smaller than a width in the horizontal direction of the first metal layer,
wherein a width in the horizontal direction of the second metal layer is smaller than the width in the horizontal direction of the fourth metal layer,
wherein each of both opposing sidewalls in the horizontal direction of the fourth metal layer is recessed than each of both opposing sidewalls in the horizontal direction of the first metal layer,
wherein each of both opposing sidewalls in the horizontal direction of the second metal layer is recessed than each of both opposing sidewalls in the horizontal direction of the fourth metal layer, and
wherein the etching composition includes an oxidizer including hydrogen peroxide (H₂O₂), a first chelating agent including a hydroxy phosphonic acid compound, a second chelating agent including a polyamine compound, and an alkali.

21-29. (canceled)
